(19) United States
(12) Patent Application Publication
(10) Pub. No.: US 2025/0338641 A1
(43) Pub. Date: Oct. 30, 2025

(54) DEEP TRENCH SIDEWALL PASSIVATION USING CONFORMAL PLASMA DOPING AND LOW-TEMPERATURE THERMAL TREATMENTS

(71) Applicant: Applied Materials, Inc., Santa Clara, CA (US)

(72) Inventors: Vikram M. BHOSLE, North Reading, MA (US); Hung Chih CHANG, Gloucester, MA (US); Nikolaos BEKIARIS, Campbell, CA (US); Seshadri RAMASWAMI, Saratoga, CA (US); Deven Raj MITTAL, Middleton, MA (US); Andy LO, San Jose, CA (US); Shashank SHARMA, Fremont, CA (US)

(73) Assignee: Applied Materials, Inc., Santa Clara, CA (US)

(21) Appl. No.: 18/647,736

(22) Filed: Apr. 26, 2024

(51) Int. Cl. H01L 27/146

(52) U.S. Cl. CPC H10F 39/011; H10F 39/807

(57) ABSTRACT

The disclosure provides approaches for forming complementary metal-oxide-semiconductor image sensors having passivated sidewalls using plasma doping and low-temperature thermal processes. One approach may include a method may include providing a main body of a complementary metal oxide semiconductor image sensor, and forming a plurality of trenches in a back side of the main body, wherein each of the plurality of trenches includes a set of sidewalls and a base extending between the set of sidewalls. The method may further include performing a plasma treatment to form a doped layer along the base and along each of the set of sidewalls, performing a thermal treatment on the doped layer, and forming a dielectric layer over the doped layer following the thermal treatment.

### FIELD OF THE DISCLOSURE

The present embodiments relate to image sensors and, more particularly, to forming a complementary metal-oxide-semiconductor image sensor with passivated sidewalls using plasma doping and low-temperature thermal processes.

### BACKGROUND OF THE DISCLOSURE

Integrated circuits (ICs) with image sensors are used in a wide range of modern-day electronic devices, such as, for example, cameras, cell phones, tablets, etc. In recent years, complementary metal-oxide-semiconductor (CMOS) image sensors (CIS) have begun to see widespread use, largely replacing charge-coupled device (CCD) image sensors. Compared to CCD image sensors, CMOS image sensors are favored due to low power consumption, small size, fast data processing, direct output of data, and low manufacturing cost. Some types of CMOS image sensors include frontside illuminated (FSI) image sensors and back side illuminated (BSI) image sensors.

IC technologies for image sensors are constantly being improved, especially with increasing demand for higher resolution and lower power consumption. Such improvements frequently involve scaling down device geometries to achieve lower fabrication costs, higher device integration density, higher speeds, and better performance. In current back side deep trench isolation (BDTI) schemes, back side passivation is critical to improve device performance. However, thermal budget for BDTI is limited because front side metallization processes are already performed.

One current approach includes using a high-k layer, such as low temperature AlOx and TaOx films, to achieve DTI passivation. However, this approach cannot be adopted in high volume manufacturing (HVM) because reduced implantation dose causes higher dark current and the high-K layer can't sustain high thermal budget.

Accordingly, improved approaches are needed for passivating sidewalls of back side deep trenches in a CIS.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a main body of a complementary metal oxide semiconductor image sensor, and forming a plurality of trenches in a back side of the main body, wherein each of the plurality of trenches includes a set of sidewalls and a base extending between the set of sidewalls. The method may further include performing a plasma treatment to form a doped layer along the base and along each of the set of sidewalls, performing a thermal treatment on the doped layer, and forming a dielectric layer over the doped layer following the thermal treatment.

In another aspect, a method of forming a complementary metal oxide semiconductor image sensor may include providing a main body comprising a front side and a back side, wherein the front side comprises one or more transistors. The method may further include forming a plurality of trenches in the back side of the main body, each of the plurality of trenches comprising a set of sidewalls and a base extending between the set of sidewalls, and performing a plasma doping process to form a doped layer along the base and along each of the set of sidewalls. The method may further include performing a thermal treatment on the doped layer, and forming a dielectric layer over the doped layer following the thermal treatment.

In yet another aspect, an apparatus for forming a complementary metal oxide semiconductor image sensor may include an ion processing tool within one or more processing chambers, the ion processing tool operable to form a doped layer along each sidewall of a plurality of trenches formed in a photodiode body, wherein the doped layer is formed using a plasma treatment, wherein a thermal treatment is performed on the doped layer, and wherein a dielectric layer is formed over the doped layer following the thermal treatment.

### BRIEF DESCRIPTION OF THE DRAWINGS

The accompanying drawings illustrate exemplary approaches of the disclosure, including the practical application of the principles thereof, as follows:

FIG. 1A illustrates a side view of a CIS, according to embodiments of the present disclosure;

FIG. 1B illustrates a front side view of the CIS, according to embodiments of the present disclosure;

FIG. 1C illustrates a back side view of the CIS, according to embodiments of the present disclosure;

FIGS. 2A-2F illustrate side views of an approach for forming a BDTI structure of the CIS, according to embodiments of the present disclosure;

FIG. 3 illustrates a perspective view of an example plasma doping system, according to embodiments of the present disclosure;

FIG. 4 illustrates a perspective view of an example processing system, according to embodiments of the present disclosure;

FIG. 5 is a flowchart of a method for forming a BDTI structure of a CIS, according to embodiments of the present disclosure;

FIG. 6 is a flowchart of a method for forming a BDTI structure of a CIS, according to embodiments of the present disclosure; and

FIG. 7 is a flowchart of a method for forming a BDTI structure of a CIS, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments of the present disclosure provide passivation of deep trench sidewalls of CIS devices using a conformal PLAD process in combination with one or more low temperature treatments. Advantageously, this results in an elevated hole concentration, which eliminates conduction peak voltage (e.g., for photodiode operating voltage of approximately 2.5V), while also significantly improving dark current characteristics.

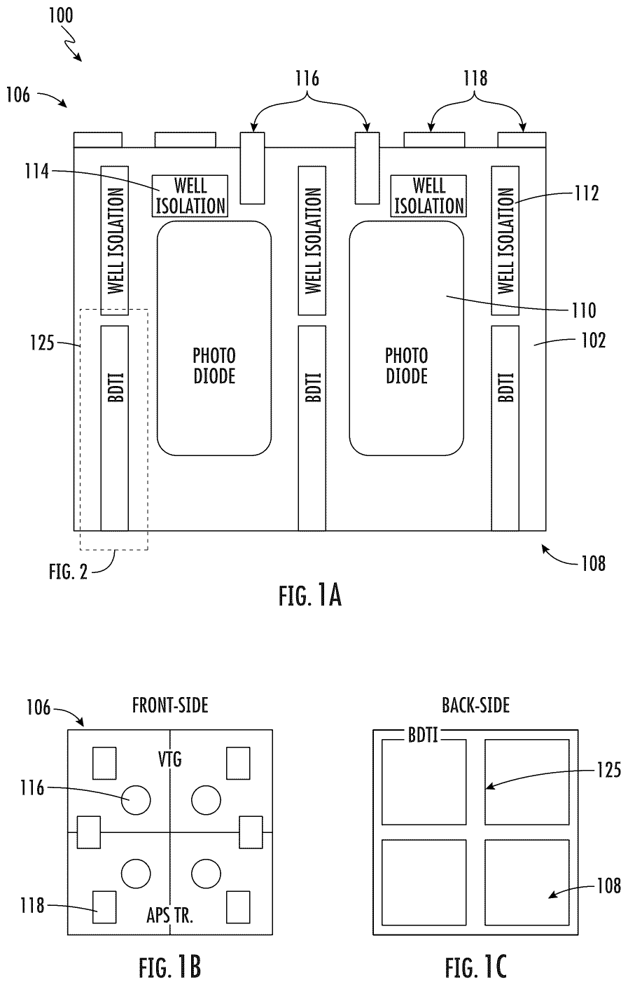

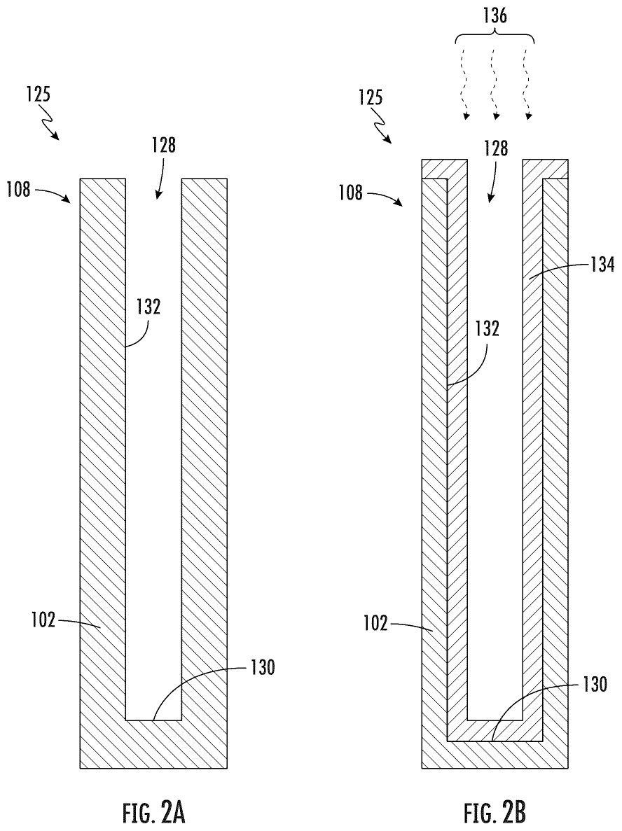

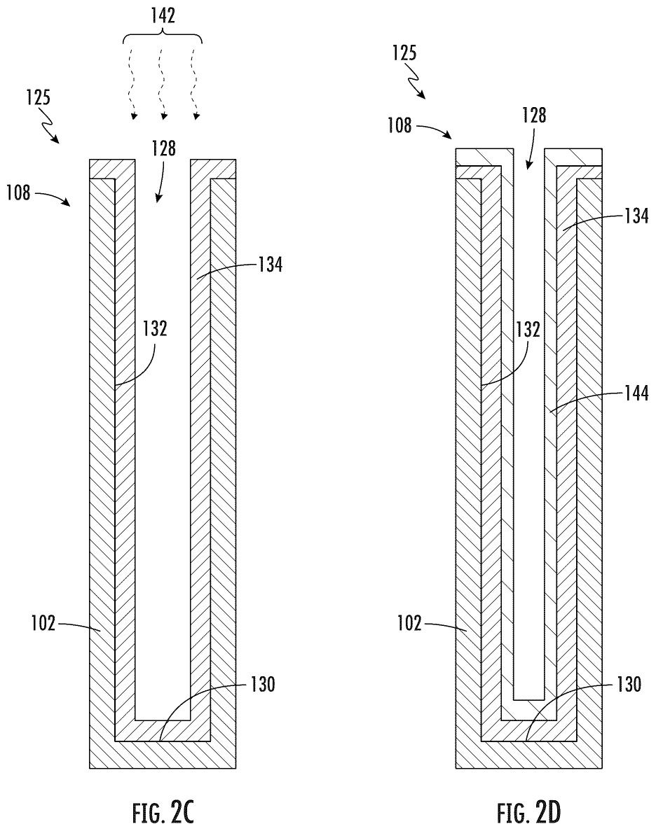

With reference to FIG. 1, an approach for forming a portion of a device 100, which may be a CIS, according to one or more embodiments will be described. The device 100 may include a photodiode (PD) body 102 having a front side 106 opposite a back side 108. The device may include a plurality of PDs 110 separated from one another by a first set of well isolations 112. A second set of well isolations 114 may be formed above the PDs 110. In some embodiments, the PDs 110 may be formed by selectively performing a first implantation process (e.g., according to a masking layer) to form a first region having a first doping type (e.g., n-type), and subsequently performing a second implantation process to form a second region having a second doping type (e.g., p-type) different than the first doping type.

Along the front side 106 may be a plurality of vertical gates 116 and a plurality of transistors 118 (e.g., active-pixel sensor). Along the back side 108 may be a plurality of BDTI structures 125 extending into the body 102, between the PDs 110.

In some embodiments, the body 102 may include multiple layers, such as a substrate, bonded to a support substrate. The substrate may be any type of semiconductor body (e.g., silicon, SiGe, SOI, etc.), as well as any other type of semiconductor and/or epitaxial layers, associated therewith. For example, in some embodiments, the substrate may include a base substrate and an epitaxial layer. In some embodiments, the substrate may include a silicon substrate. In some embodiments, the substrate may be thinned after bonding to the support substrate, wherein thinning the substrate allows for radiation to pass more easily to an image sensing element subsequently formed within the substrate. In various embodiments, the support substrate may also be thinned by etching and/or mechanical grinding.

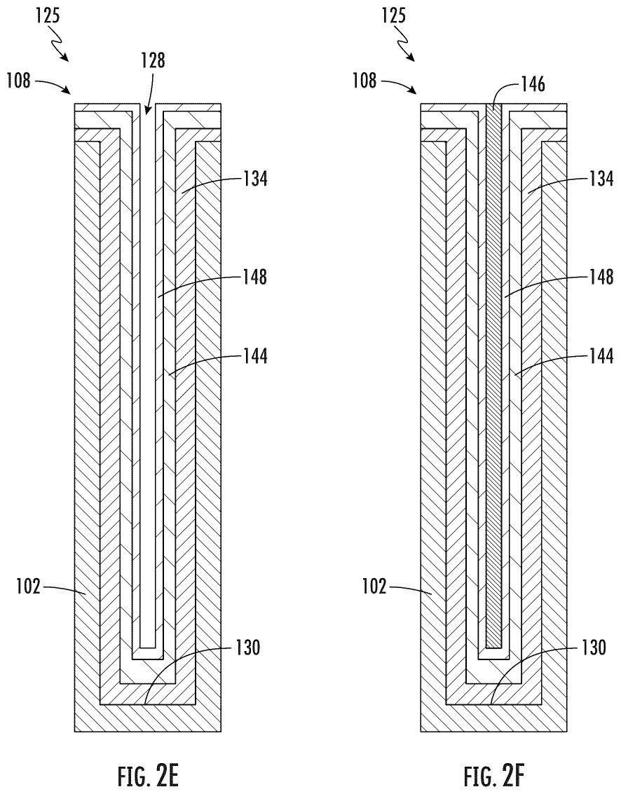

FIGS. 2A-2F demonstrate a non-limiting approach for forming the BDTI structures 125. As shown in FIG. 2A, a trench 128 may be formed in the back side 108 of the body 102, the trench 128 having a base 130 and a set of sidewalls 132 extending vertically, or substantially vertically, from the base 130. In other embodiments, the trench 128 may include tapered sidewalls that cause a width of the trench 128 to decrease as a distance from the back side 108 of the body 102 increases. It will be understood that the trench 128 may be formed by any number of masking and subtraction processes to achieve a cavity having a desired depth and width.

As shown in FIG. 2B, a doped layer 134 may then be formed within the trench 128, along the sidewalls 132 and the base 130. The doped layer 134 may be a conformal layer, which is formed by delivering diborane ions (B₂H₆) into the exposed surfaces of the trench 128 until a desired dopant concentration is achieved. The doped layer 124 may be formed using a plasma treatment 136, such as a plasma doping (PLAD) process, which impacts the sidewalls 132 and the base 130. Other dopants may be used in other embodiments.

As shown in FIG. 2C, a thermal treatment 142 may then be performed on the trench 128 and the doped layer 134. In some embodiments, the thermal treatment 142 may be a dynamic surface annealing (DSA) process performed at a temperature greater than 600° C. and for a time duration between 250 microseconds and 1 millisecond. In other embodiments, the thermal treatment 142 may be a rapid thermal process (e.g., anneal) performed at a temperature between 400° C. and 450° C. and for a time duration between 30 minutes and 60 minutes. Embodiments herein are not limited in this context, however.

As shown in FIG. 2D, a dielectric layer 144 may then be formed over the doped layer 134, within the trench 128. The dielectric layer 144 may be a passivation layer, which is grown or deposited using a chemical oxidation process or a rapid thermal oxidation process. In some embodiments, the dielectric layer 144 may be an oxide, such as aluminum oxide (Al₂Oₓ).

As shown in FIG. 2E, an optional high-k dielectric layer 148 may be formed over the oxide layer 144. In some embodiments, the high-k dielectric layer 148 may include titanium nitride (TiN), hafnium oxide (HfO₂), titanium oxide (TiO₂), hafnium zirconium oxide (HfZrO), tantalum oxide (Ta₂O₃), hafnium silicon oxide (HfSiO₄), zirconium oxide (ZrO₂), zirconium silicon oxide (ZrSiO₂), etc. The high-k dielectric layer 148 may be deposited by a physical vapor deposition technique (e.g., PVD, CVD, PE-CVD, ALD, etc.).

As shown in FIG. 2F, the trench 128 may be subsequently filled with one or more reflective filler materials 146. In various embodiments, the one or more reflective filler materials 146 may comprise aluminum (Al), rhodium (Rh), ruthenium (Ru), copper (Cu), silver (Ag), gold (Au), tungsten (W), cobalt (Co), iron (Fc), molybdenum (Mo), titanium (Ti), chromium (Cr). Other filler materials may be possible in alternative embodiments. During processing, the reflective filler material(s) 146 may be deposited and then planarized.

Although not shown, processing of the device 100 may continue, e.g., by forming a plurality of color filters along the back side 108. In some embodiments, a dielectric planarization structure may be arranged over a layer of dielectric material, and the color filters may be formed over the dielectric planarization structure. In some embodiments, the plurality of color filters may be formed within openings in a grid structure overlying the layer of dielectric material. In some embodiments, the plurality of color filters may be formed by forming a color filter layer and patterning the color filter layer. The color filter layer is formed of a material that allows for the transmission of radiation (e.g., light) having a specific range of wavelength, while blocking light of wavelengths outside of the specified range.

A plurality of micro-lenses (not shown) may then be formed over the plurality of color filters. In some embodiments, the plurality of micro-lenses may be formed by depositing a micro-lens material above the plurality of color filters (e.g., by a spin-on method or a deposition process). A micro-lens template having a curved upper surface is patterned above the micro-lens material. In some embodiments, the micro-lens template may comprise a photoresist material exposed using an exposing light dose (e.g., for a negative photoresist more light is exposed at a bottom of the curvature and less light is exposed at a top of the curvature), developed and baked to form a rounding shape. The plurality of micro-lenses are then formed by selectively etching the micro-lens material according to the micro-lens template.

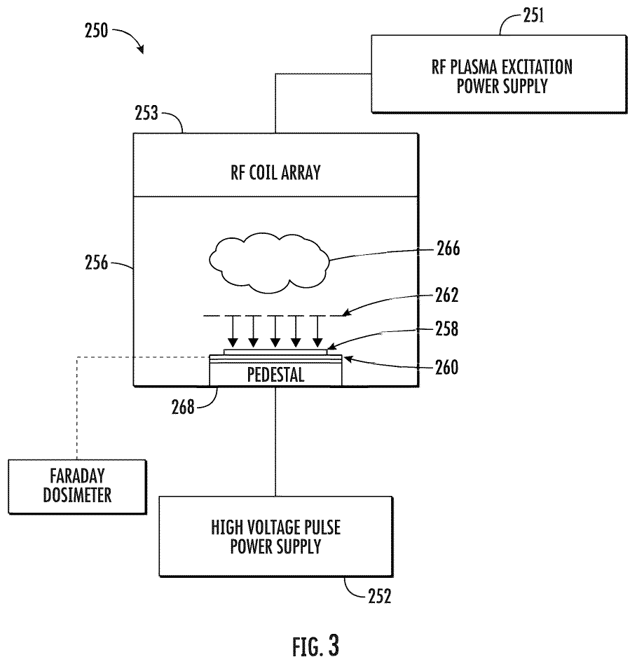

FIG. 3 demonstrates an example PLAD tool or system 250, which provides pulsed RF-excited continuous plasma doping. The system 250 may be operable to form the doped layer 134 described above. As shown, the system 250 may include a plasma power supply 251, a voltage pulse power supply 252, an RF coil array 253, and a dosimeter 254. Within a plasma chamber 256 is a wafer/substrate 258. A platen/pedestal 260 may support the wafer 258, and a sheath 262 may be formed above the wafer 258. The dosimeter 254 may be a Faraday dosimeter or other type of sensor that directly measures the dose of ions received by the wafer 258. Although non-limiting, the dosimeter can be located on the pedestal 260, proximate to the wafer 258.

During use, the plasma power supply 252 and the RF coil array 253 deliver radio frequency excitation to generate a plasma 266 when gaseous species are delivered into the plasma chamber 256. For example, the plasma power supply 251 may be an RF powered inductively coupled power source to generate inductively coupled plasma 266, as known in the art. Gaseous species may be delivered from one or more gas sources (not separately shown) to generate radicals and/or ions of any suitable species, such as B₂H₆.

The voltage pulse power supply 252 may generate a bias voltage between the wafer 258 and the plasma chamber 256. As such, when the voltage pulse power supply 252 generates a voltage between the plasma chamber 256 and the substrate 258, a similar, but slightly larger, voltage difference is generated between the plasma 266 and the substrate 258. In one non-limiting example, a 5000 (5 kV) voltage difference established between the plasma chamber 256 and the substrate 258 (or, equivalently, pedestal 214) may generate a voltage difference of approximately 5005 V to 5030 V between the plasma 266 and the substrate 258.

In some embodiments, the voltage pulse power supply 252 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 250 may further include a controller (not shown), to control the pulsing routine applied to the substrate 258.

According to various embodiments, the plasma 266 may be formed at least in part of ions that constitute an amorphizing species, wherein the amorphizing species may be any suitable ion capable of amorphizing an initially crystalline region of materials, such as the substrate 258 and/or layers formed atop the substrate, such as the doped layer 134 formed along the surfaces of the trench 128 (FIG. 2B). When the plasma 266 is present in the plasma chamber 256, the controller may generate a signal for the voltage pulse power supply 252 to apply a pulse routine to the substrate 258, where the pulse routine constitutes a plurality of extraction voltage pulses. As such, when the extraction voltage pulses are applied between the substrate 258 and plasma 266, ions are extracted in pulsed form from the plasma 266, generating a plurality of ion pulses that are directed to the substrate 258.

In some embodiments, the platen/pedestal 260 may include an external or internal heating element 268, such as a resistive heater, or may be heated using radiant heat, such as heating lamps disposed above or below the platen/pedestal 260. In other embodiments, the heating element 268 may additionally, or alternatively, be located in a load lock chamber or a separate pre-heat chamber to pre-heat the wafer before it reaches the platen/pedestal 260.

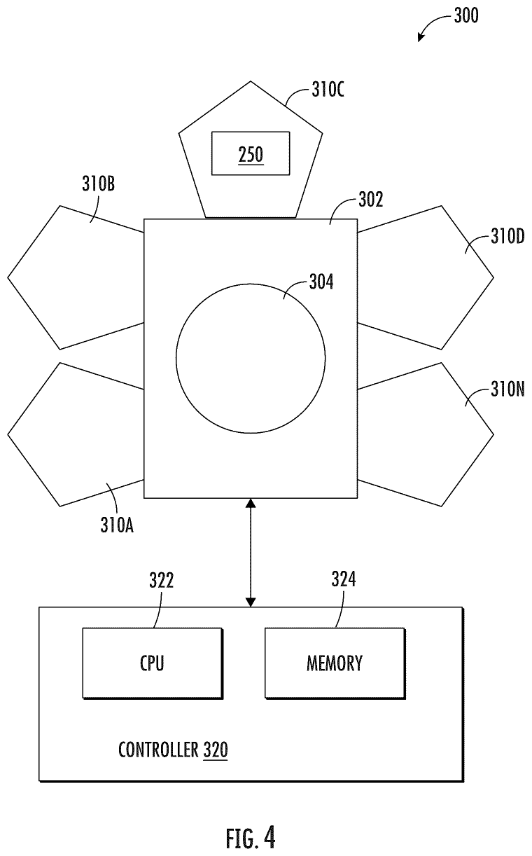

FIG. 4 shows a schematic of another example system/apparatus 300 according to embodiments of the disclosure. In some embodiments, the system 300 may be a cluster tool operable to perform processes necessary to form the device 100 described herein. Although non-limiting, the system 300 may include at least one central transfer station/chamber 302 and one or more robots 304 within the transfer station/chamber 302, wherein the robot 304 is operable to move a robot blade and a wafer to and from each of a plurality of processing chambers 310A-310N connected with, or positioned adjacent to, the transfer station/chamber 302. In some embodiments, the processing chambers 310A-310N may support ion implantation, material deposition, and material etching. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 310A may be a deposition chamber operable to deposit one or more layers of the device 100. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition.

In some embodiments, processing chamber 310B may be an etch chamber operable to form trenches through the body of the device 100. In some embodiments, processing chamber 310B may be used for wet and/or dry etch processes. In some embodiments, the processing chamber 310B may be operable to planarize the devices 100, e.g., to partially remove material.

In some embodiments, processing chamber 310C may be operable to perform a plasma treatment to the device 100. For example, processing chamber 310C may include PLAD tool or system 250. In some embodiments, the system 250 is operable to form the doped layer along each sidewall of trenches formed in the photodiode body.

In some embodiments, processing chamber 310D may be operable to perform one or more thermal treatments, such as a dynamic surface annealing process and or a rapid thermal process.

A system controller 320 is in communication with the robot 304, the transfer station/chamber 302, and the plurality of processing chambers 310A-310N. The system controller 320 can be any suitable component that can control the processing chambers 310A-310N and robot(s) 304, as well as the processes occurring within the process chambers 310A-310N. For example, the system controller 320 can be a computer including a central processor 322, memory 324, suitable circuits/logic/instructions, and storage.

Processes or instructions may generally be stored in the memory 324 of the system controller 320 as a software routine that, when executed by the processor 322, causes the processing chambers 310A-310N to perform processes of the present disclosure. The software routine may also be stored and/or executed by a second processor (not shown) that is remotely located from the hardware being controlled by the processor 322. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 322, transforms the general-purpose computer into a specific purpose computer (controller) that controls the chamber operation such that the processes are performed.

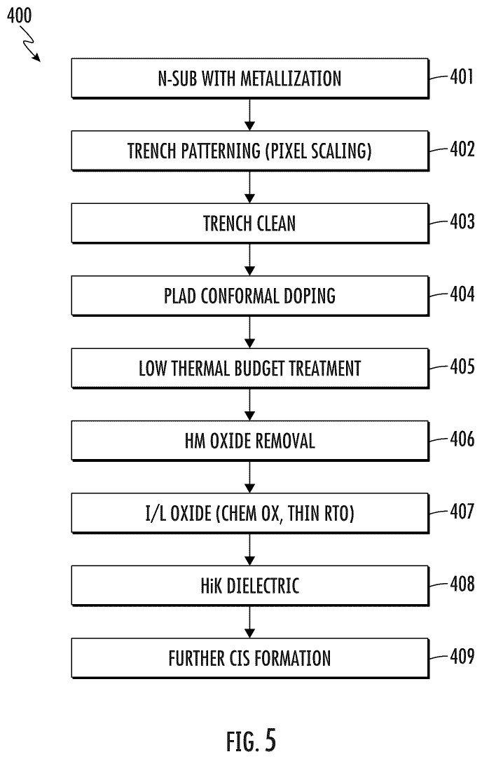

FIG. 5 is a flowchart of one method 400 for forming a BDTI structure of a CIS. At block 401, the method 400 may include forming a N-substrate with metallization. In some embodiments, one or more transistors and one or more gates may be formed along a front side of the substrate.

At block 402, the method 400 may include trench patterning (pixel scaling), and at block 403, the trenches may be cleaned. In some embodiments, the trenches are formed in a back side of the substrate.

At block 404, the method 400 may include performing a plasma doping process to form a doped layer along a base and along a set of sidewalls of the trenches. In some embodiments, the plasma treatment includes directing diborane ions into the plurality of trenches.

At block 405, the method 400 may include a thermal treatment performed on the doped layer. In some embodiments, the thermal treatment is a dynamic surface annealing process performed at a temperature greater than 600° C. and for a time duration between 250 microseconds and 1 millisecond. In some embodiments, the thermal treatment is a rapid thermal process performed at a temperature between 400° C. and 450° C. and for a time duration between 30 minutes and 60 minutes.

At block 406, the method 400 may include removing a hardmask, and at block 407 the method 400 may include forming an interlayer (I/L) oxide within the trench. In some embodiments, the I/L oxide may be Al₂Oₓ, which is formed using a chemical oxidation process or a thin rapid thermal oxidation process.

At block 408, the method 400 may optionally include forming a high-k dielectric layer over the oxide layer within the trench. In some embodiments, the high-k dielectric layer may include titanium nitride (TiN).

At block 409, the method 400 may include performing additional CIS processes, such as subsequently filling the trench with one or more reflective filler materials. In some embodiments, the reflective filler material(s) is formed directly atop the high-k layer or directly atop the oxide layer, e.g., in the case that no high-k layer is present.

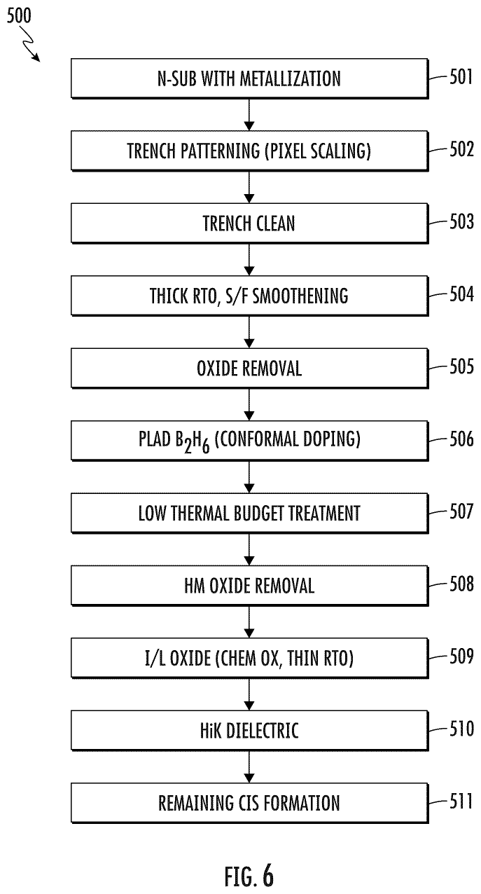

FIG. 6 is a flowchart of another method 500 for forming a BDTI structure of a CIS. At block 501, the method 500 may include forming a N-substrate with metallization. In some embodiments, one or more transistors and one or more gates may be formed along a front side of the substrate.

At block 502, the method 500 may include trench patterning (pixel scaling), and at block 503, the trenches may be cleaned. In some embodiments, the trenches are formed in a back side of the substrate.

At block 504, the method 500 may include forming a sacrificial oxide layer within the trench and then performing smoothening process. In some embodiments, a rapid thermal oxidation process, a decoupled plasma oxidation (DPO), or a remote plasma oxygen (RPO) process may be used to grow a thick screen oxide (RTO) within the trench to a desired thickness (e.g., 5 to 20 nm). In some embodiments, the smoothening process is a sulfur hexafluoride (SF₆) plasma applied to the sacrificial oxide layer.

At block 505, the method 500 may include removing the sacrificial layer using, e.g., a wet or dry etch.

At block 506, the method 500 may include performing a plasma doping process to form a doped layer conformally along a base and along a set of sidewalls of the trenches. In some embodiments, the plasma treatment includes directing diborane ions into the plurality of trenches.

At block 507, the method 500 may include a low-budget thermal treatment performed on the doped layer. In some embodiments, the thermal treatment is a dynamic surface annealing process performed at a temperature greater than 600° C. and for a time duration between 250 microseconds and 1 millisecond. In some embodiments, the thermal treatment is a rapid thermal process performed at a temperature between 400° C. and 450° C. and for a time duration between 30 minutes and 60 minutes.

At block 508, the method 500 may include removing an oxide hardmask, and at block 509 the method 500 may include forming an I/L oxide within the trench. In some embodiments, the I/L oxide may be Al₂Oₓ, which is formed using a chemical oxidation process or a thin rapid thermal oxidation (RTO) process.

At block 510, the method 500 may optionally include forming a high-k layer over the oxide layer within the trench. In some embodiments, the high-k layer may include titanium nitride (TiN).

At block 511, the method 500 may include performing additional CIS processes, such as subsequently filling the trench with one or more reflective filler materials. In some embodiments, the reflective filler material(s) is formed directly atop the high-k layer or directly atop the oxide layer, e.g., in the case that no high-k layer is present.

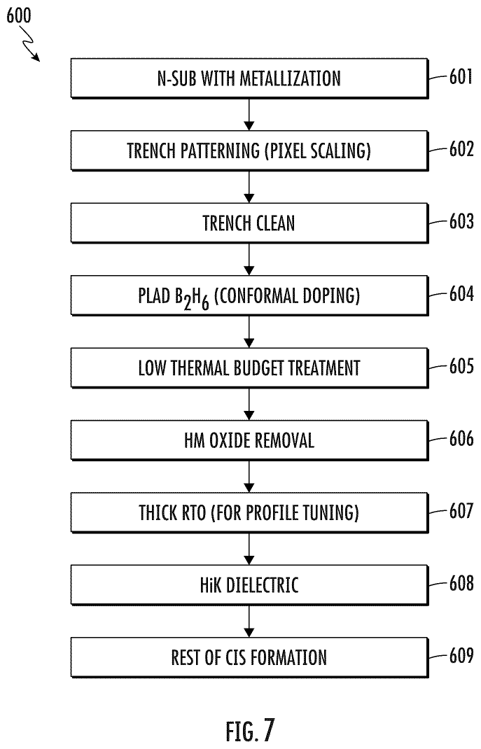

FIG. 7 is a flowchart of another method 600 for forming a BDTI structure of a CIS. At block 601, the method 600 may include forming a N-substrate with metallization. In some embodiments, one or more transistors and one or more gates may be formed along a front side of the substrate.

At block 602, the method 600 may include trench patterning (pixel scaling), and at block 603, the trenches may be cleaned. In some embodiments, the trenches are formed in a back side of the substrate.

At block 604, the method 600 may include performing a plasma doping process to form a doped layer conformally along a base and along a set of sidewalls of the trenches. In some embodiments, the plasma treatment includes directing diborane ions into the plurality of trenches.

At block 605, the method 600 may include a low-budget thermal treatment performed on the doped layer.

At block 606, the method 600 may include removing an oxide hardmask, and at block 607 the method 600 may include forming an I/L oxide within the trench. In some embodiments, the I/L oxide may be a thick layer for profile tuning.

At block 608, the method 600 may optionally include forming a high-k layer over the oxide layer within the trench.

At block 609, the method 600 may include performing additional CIS processes, such as subsequently filling the trench with one or more reflective filler materials. In some embodiments, the reflective filler material(s) is formed directly atop the high-k layer or directly atop the oxide layer, e.g., in the case that no high-k layer is present.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
providing a main body of a complementary metal oxide semiconductor image sensor;
forming a plurality of trenches in a back side of the main body, each of the plurality of trenches comprising a set of sidewalls and a base extending between the set of sidewalls;
performing a plasma treatment to form a doped layer along the base and along each of the set of sidewalls;
performing a thermal treatment to the back side of the main body; and
forming a dielectric layer over the doped layer following the thermal treatment.

2. The method of claim 1, further comprising forming a high-k dielectric layer over the dielectric layer.

3. The method of claim 1, wherein the thermal treatment is a dynamic surface annealing process performed at a temperature greater than 600° C. and for a time duration between 250 microseconds and 1 millisecond.

4. The method of claim 1, wherein the thermal treatment is a rapid thermal anneal performed at a temperature between 400° C. and 450° C. and for a time duration between 30 minutes and 60 minutes.

5. The method of claim 1, wherein the plasma treatment comprises directing diborane ions into the plurality of trenches.

6. The method of claim 1, wherein forming the dielectric layer comprises one of:
performing a rapid thermal oxidation process, and performing a chemical oxidation process.

7. The method of claim 1, further comprising forming a sacrificial oxide within the plurality of trenches prior to performing the plasma doping.

8. The method of claim 1, further comprising forming a reflective filler within the plurality of trenches after the dielectric layer is formed.

9. A method of forming a complementary metal oxide semiconductor image sensor, the method comprising:
providing a main body comprising a front side and a back side, and wherein the front side comprises one or more transistors;
forming a plurality of trenches in the back side of the main body, each of the plurality of trenches comprising a set of sidewalls and a base extending between the set of sidewalls;
performing a plasma doping process to form a doped layer along the base and along each of the set of sidewalls;
performing a thermal treatment on the doped layer; and
forming an dielectric layer over the doped layer following the thermal treatment.

10. The method of claim 9, further comprising forming a high-k dielectric layer over the dielectric layer.

11. The method of claim 9, wherein the thermal treatment is a dynamic surface annealing process performed at a temperature greater than 600° C. and for a time duration between 250 microseconds and 1 millisecond.

12. The method of claim 9, wherein the thermal treatment is a rapid thermal anneal performed at a temperature between 400° C. and 450° C. and for a time duration between 30 minutes and 60 minutes.

13. The method of claim 9, wherein the plasma doping process comprises directing diborane ions into the plurality of trenches.

14. The method of claim 9, wherein forming the dielectric layer comprises one of:
performing a rapid thermal oxidation process, and performing a chemical oxidation process.

15. The method of claim 9, further comprising forming a sacrificial oxide within the plurality of trenches prior to performing the plasma doping.

16. The method of claim 9, further comprising forming a reflective filler within the plurality of trenches after the dielectric layer is formed.

17. An apparatus for forming a complementary metal oxide semiconductor image sensor, the apparatus comprising an ion processing tool within one or more processing chambers, the ion processing tool operable to: form a doped layer along each sidewall of a plurality of trenches formed in a photodiode body, wherein the doped layer is formed using a plasma treatment, wherein a thermal treatment is performed on the doped layer, and wherein an dielectric layer is formed over the doped layer following the thermal treatment.

18. The apparatus of claim 17, wherein the ion processing tool is a plasma doping tool.

19. The apparatus of claim 18, wherein the plasma doping tool is operable to deliver diborane ions into the plurality of trenches.
